(19) United States
(12) Patent Application Publication
(10) Pub. No.: US 2017/0064812 A1
(43) Pub. Date: Mar. 2, 2017

(54) PRINTED CIRCUIT BOARD FOR ALLOWING DETECTION OF A FALLEN OFF PART AND CIRCUIT FOR DETECTING A FALLEN OFF PART

(71) Applicant: FANUC CORPORATION, Minamitsuru-gun (JP)

(72) Inventors: Takahiro Baba, Minamitsuru-gun (JP); Kazuki Sakamoto, Minamitsuru-gun (JP)

(73) Assignee: FANUC CORPORATION, Minamitsuru-gun (JP)

(21) Appl. No.: 15/244,457

(22) Filed: Aug. 23, 2016

(30) Foreign Application Priority Data
Aug. 27, 2015 (JP) 2015-167689

(51) Int. Cl. H05K 1/02; H05K 1/18

(52) U.S. Cl. CPC H05K 1/0213; H05K 1/18

(57) ABSTRACT

A printed circuit board allows detection of whether or not a part that is mounted on the printed circuit board and that is not electrically connected to the printed circuit board for conventional use has fallen off from the printed circuit board, and is provided with a number of conductive members that make contact with a number of connection portions, respectively, provided on the above-described mounted part and that are used for determining whether or not the above-described mounted part has fallen off from the above-described printed circuit board.

### BACKGROUND OF THE INVENTION

### Field of the Invention

The present invention relates to a printed circuit board having a function of detecting a part that has fallen off from a printed circuit board and to a fallen off part detection circuit for detecting the part that has fallen off.

Printed circuit boards having electronic parts mounted thereon are used for various types of electronics. In a printed circuit board inside the numerical controller of a machine tool, a part mounted on the printed circuit board in accordance with a method other than soldering, for example, by means of an adhesive or a resin, may fall off when the adhesion portion is cracked or deteriorated because of the vibration or the adhering of the splashed cutting fluid during the operation of the machine tool (see Japanese Unexamined Patent Publication H9 (1997)-316388).

In the case where a fin for heat dissipation is joined to the top of a heat source part such as a CPU by an adhesive, and the fin for heat dissipation falls off due to the deterioration of the adhesive, for example, the temperature of the heat source part increases, and continuous use of the heat source part at the rated temperature causes the heat source part to break. As a method to solve this problem, a technology for monitoring the temperature by providing a temperature sensor in the vicinity of the heat source part is known. However, there is a delay in notifying the alarm after the fin has fallen off because it takes time for the temperature to rise. In addition, a circuit for the temperature sensor is necessary, and an increase in the temperature may not be monitored precisely due to a flow of air or another heat source in the vicinity depending on the location where the temperature sensor is placed.

### SUMMARY OF THE INVENTION

An object of the present invention is to provide a printed circuit board having a function of detecting a part that has fallen off from the printed circuit board and a fallen off part detection circuit for detecting the part that has fallen off.

The printed circuit board according to the present invention allows for the detection of whether or not a part that is mounted on a printed circuit board and is not electrically connected to the printed circuit board for conventional use has fallen off the printed circuit board, and is characterized by being provided with a number of conductive members that make contact with a number of conductive connection portions provided with the above-described mounted part and are used to determine whether or not the mounted part has fallen off the printed circuit board.

Here, the expression, “the mounted part is not electrically connected to the printed circuit board for conventional use,” means that it is not necessary to electrically connect the mounted part to the printed circuit board in order to use the mounted part for its function. The resin portions of the below-described fin for heat dissipation or connector are not electrically connected to the printed circuit board.

The above-described conductive members may be male or female terminals that make contact with female or male conductive connections provided on the mounted part.

The above-described connection portions and the above-described conductive members may make contact with each other via coil springs.

The fallen off part detection circuit according to the present invention detects whether or not a part that is mounted on a printed circuit board and is not electrically connected to the printed circuit board for conventional use has fallen off, and is characterized by having: a structure where a number of conductive connection portions provided with the mounted part are electrically connected to each other; conductive members that are provided on the printed circuit board and that make contact with the above-described conductive connection portions; and a determination unit for electrically detecting whether or not the above-described conductive connection portions and the above-described conductive members are electrically connected to each other and for determining whether or not the above-described mounted part has fallen off from the above-described printed circuit board.

The above-described conductive members may be male or female terminals that make contact with female or male conductive connections provided on the mounted part.

The above-described connection portions and the above-described conductive members may make contact with each other via coil springs.

The present invention can provide a printed circuit board having a function of detecting a part that has fallen off from a printed circuit board and a fallen off part detection circuit for detecting the part that has fallen off.

### BRIEF DESCRIPTION OF THE DRAWINGS

The above-described and other objects and features of the present invention will be clarified from the descriptions of the embodiments below in reference to the accompanying drawings, from among which:

FIG. 1 is a diagram showing an embodiment for detecting a fin for heat dissipation that has fallen off;

FIG. 2 is a diagram showing a circuit for detecting a fallen off part;

FIG. 3 is a diagram showing an embodiment for detecting a fallen off connector;

FIG. 4 is a diagram showing an embodiment according to the present invention having a coil spring structure; and

FIG. 5 is a flow chart for carrying out a process for detecting a fallen off part.

### DETAILED DESCRIPTION OF THE PREFERRED EMBODIMENTS

In the following, the embodiments of the present invention are described in reference to the drawings. Here, the same symbols are used in the descriptions for the same members or similar components in different embodiments.

In the present invention, a part that needs to be detected at the time of falling off is mounted on a printed circuit board 1, and a conductive terminal is provided in two places on the printed circuit board 1 beneath the part. When the part is mounted, a portion of the part is inserted into each conductive terminal provided on the printed circuit board 1.

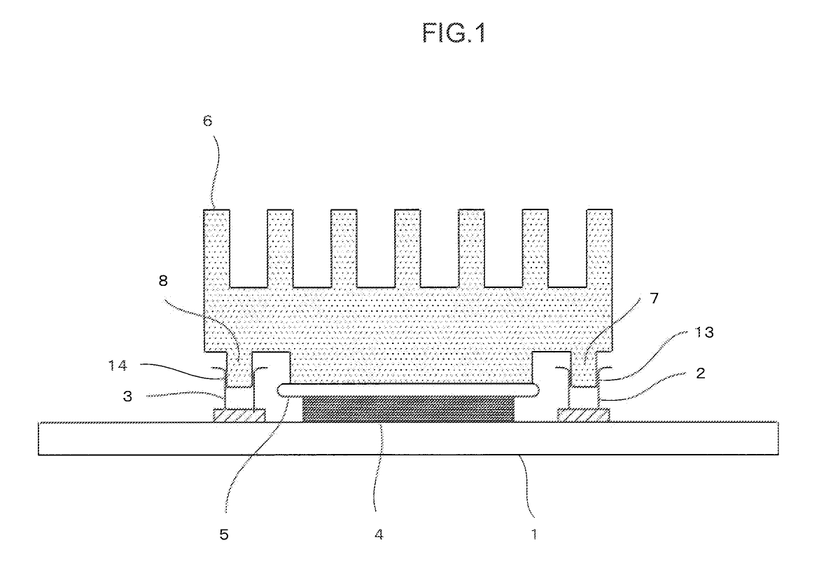

FIG. 1 is a diagram showing the embodiment for detecting whether or not a fin for heat dissipation has fallen off. A fin for heat dissipation 6 is adhered to a CPU 4, which is a heat source part, on the printed circuit board 1 by means of an adhesive 5. A terminal 2 or 3, which are conductive members, is provided in either of the two places around the CPU 4 on the printed circuit board 1. In the case where the part is conductive as the fin for heat dissipation 6, the part has such a form as to be able to be inserted into the conductive terminals 2 and 3, and a number of conductive connection portions 7 and 8 that are provided therein are electrically connected to each other in the structure. The terminals 2 and 3 may be either a male type or a female type. Correspondingly, the connection portions of the fin for heat dissipation 6 may be either a female type or a male type. Though the figure shows a pair of connections, two or more pairs of connections may be formed.

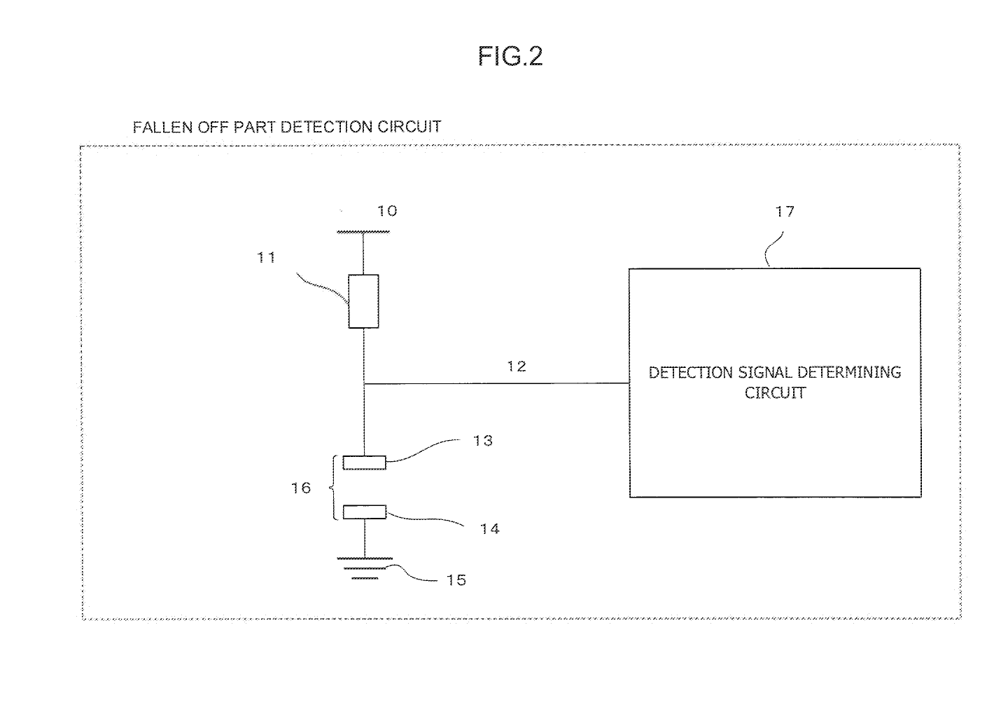

FIG. 2 is a diagram showing a circuit for detecting whether or not a part has fallen off, and the circuit detects a part that has fallen off from the printed circuit board 1. A resistor 11 and a part (fin for heat dissipation 6) that connects contacts 13 and 14 to each other are provided in series between a power supply voltage 10 and the ground voltage (0 V) on the ground 15. A voltage generated between the resistor 11 and the contact 13 is used as a detection signal. The contacts 13 and 14 represent the contacts between the connection portions 7 and 8 of the fin for heat dissipation 6 and the conductive terminals 2 and 3 on the printed circuit board 1.

When the fin for heat dissipation 6 is mounted normally, the contacts 13 and 14 are electrically connected to each other through the fin for heat dissipation 6, and therefore, the detection signal 12 becomes the ground voltage. 16 indicates the electrical connection by the part (fin for heat dissipation 6). In contrast, in the case where the fin for heat dissipation 6 has fallen off, the contacts 13 and 14 are not electrically connected, and therefore, the voltage of the detection signal 12 and the power supply voltage 10 have equal voltage values. The detection signal 12 is inputted into a detection signal determining circuit, where it is determined that the part has not fallen off when the voltage of the signal is equal to the ground voltage and that the part has fallen off when the voltage of the signal is equal to the power supply voltage. An alarm is displayed or the system is stopped depending on the results of determination by the detection signal determining circuit 17.

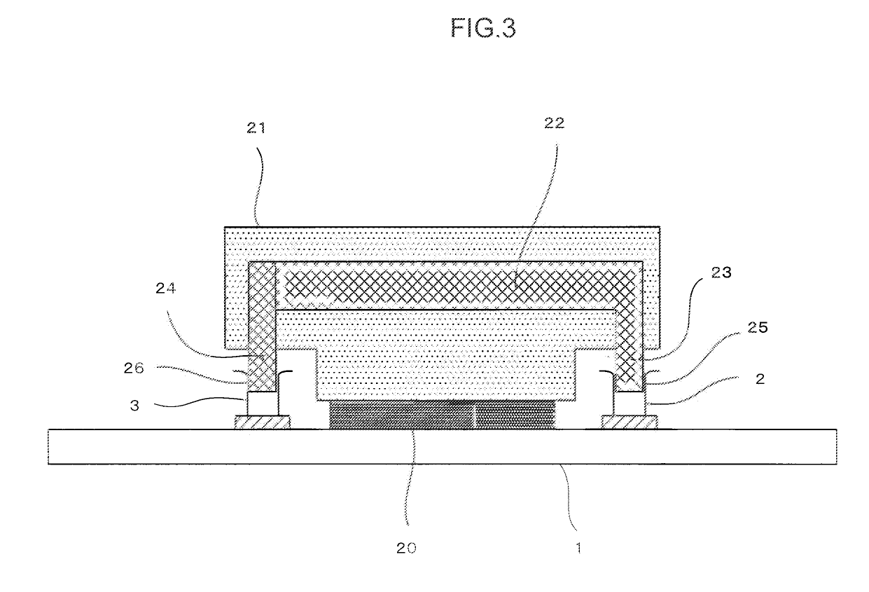

FIG. 3 is a diagram showing an embodiment for detecting whether or not a connector has fallen off. In the case where the part is not conductive, a conductive member is provided to the part, and in addition, the conductive member has a form so as to be able to be inserted into conductive terminals on the printed circuit board such that a number of conductive contacts can be electrically connected to each other in the structure. When the part is mounted normally, the terminals are electrically connected through the part. In the case where the part has fallen off, a fallen off part detection circuit provided on the printed circuit board detects the part that has fallen off.

In FIG. 3, conductive terminals 2 and 3 are provided on the printed circuit board 1. An example of a part that is not conductive is a connector 21. A connector 21 is provided with a conductive member 22. The connector 21 is connected to a socket 20 that is fixed to the printed circuit board 1. When the connector 21 is fixed to the socket 20, connection portions 23 and 24 at the two ends of the conductive member 22 are connected to the terminals 2 and 3.

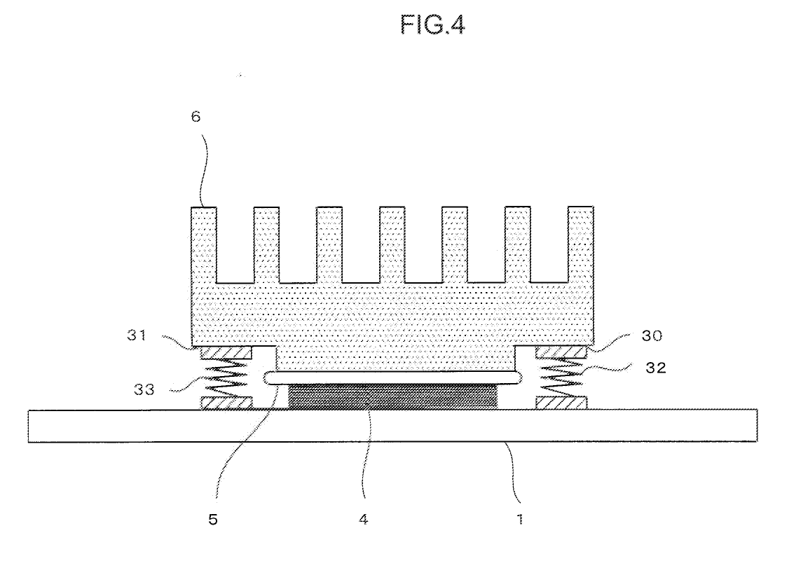

FIG. 4 shows an embodiment in the case where conductive terminals having a coil spring structure are used instead of a socket. The terminals having a coil spring structure can vary the contact locations, which increases the freedom in the height of the contact locations, and therefore, there is such an advantage that the part is not required to have a complex form even in the contact portions. One end of the conductive terminal 32 or 33 having a coil spring structure is attached to the printed circuit board 1. The other end of the conductive terminal 32 having a coil spring structure is electrically connected to the fin for heat dissipation 6 via the contact 30. The other end of the conductive terminal 33 having a coil spring structure is electrically connected to the fin for heat dissipation 6 via the contact 31.

The present embodiment can be applied to parts having different shapes and heights, and thus, it becomes unnecessary to make the shape of the part complex. It also becomes unnecessary to mount conductive terminals with high precision.

In the case of terminals having a coil spring structure, however, it is possible for the contact failure to be temporary due to vibrations. In such a case (not shown), it is possible to add a capacitor (not shown) between the detection signal and the ground so that the temporary change in the signal can be suppressed or to allow the fallen off part detection circuit to determine whether or not the part has fallen off from the results of sampling a number of times.

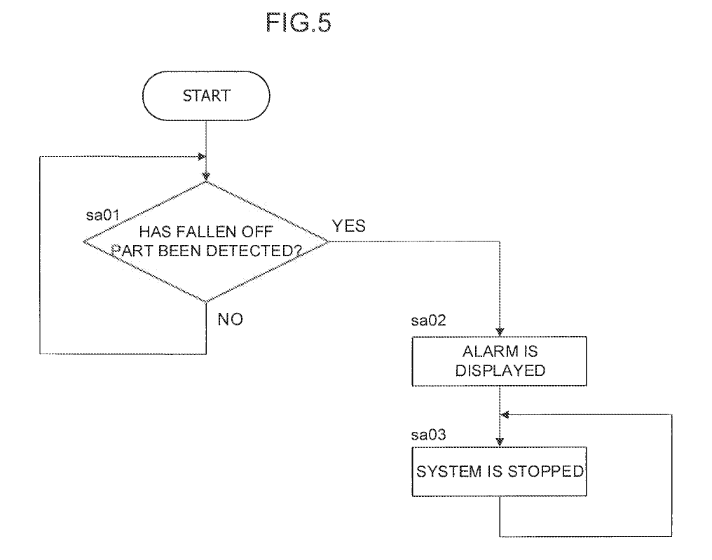

Next, the flow chart for detecting a fallen off part is described in reference to FIG. 5. Whether or not a part has fallen off is continuously monitored, and once a fallen off part is detected, an alarm is displayed and the system is stopped. This is described in accordance with the following steps.
[Step sa01] Whether or not a fallen off part has been detected is determined. The process in step sa01 is repeated in the case where the part has not fallen off, and the procedure moves to step sa02 in the case where the part has fallen off.
[Step sa02] An alarm is displayed.
[Step sa03] The system is stopped, and this state is maintained.

As described above, according to the present invention, a fallen off part can be electrically monitored so as to be instantly detected, and a very quick notification is possible before the system goes out of order. In addition, the circuit structure can be made simple as compared to a temperature monitoring circuit for monitoring the temperature of the heat source part, and thus, there is an advantage in terms of the cost.

Though the embodiments of the present invention are described in the above, the present invention is not limited to the above-described embodiments and can be implemented in other modes by applying appropriate modifications.

1. A printed circuit board for allowing detection of whether or not a part that is mounted on the printed circuit board and that is not electrically connected to the printed circuit board for conventional use has fallen off from said printed circuit board, comprising a number of conductive members that make contact with a number of conductive connection portions, respectively, provided in said mounted part and that are used for determining whether or not said mounted part has fallen off from said printed circuit board.

2. The printed circuit board according to claim 1, characterized in that said conductive members are male or female terminals to make contact with conductive female or male contacts provided on said mounted part.

3. The printed circuit board according to claim 1, characterized in that said contact portions and said conductive members make contact with each other via coil springs.

4. A fallen off part detection circuit for detecting whether or not a part that is mounted on a printed circuit board and that is not electrically connected to the printed circuit board for conventional use has fallen off from the printed circuit board, characterized by comprising:
a structure where a number of conductive connection portions provided with said mounted part are electrically connected to each other;
conductive members that are provided on said printed circuit board and make contact with said conductive connection portions, respectively; and
a determination unit for electrically detecting whether or not said conductive connection portions and said conductive members are electrically connected to each other, and for determining whether or not said mounted part has fallen off from said printed circuit board.

5. The fallen off part detection circuit according to claim 2, characterized in that said conductive members are male or female terminals to make contact with conductive female or male contacts provided on said mounted part.

6. The fallen off part detection circuit according to claim 1, characterized in that said connection portions and said conductive member make contact with each other via coil springs.
